(19) United States
(12) Patent Application Publication
(10) Pub. No.: US 2016/0204123 A1
(43) Pub. Date: Jul. 14, 2016

(54) Method of fabricating three-dimensional semiconductor devices, and three-dimensional semiconductor devices thereof

(71) Applicant: MACRONIX INTERNATIONAL CO., LTD., Hsinchu (TW)

(72) Inventors: Ta-Hone Yang, Miaoli County (TW); Shih-Ping Hong, Taichung (TW); Nan-Tsu Lian, Hsinchu (TW); Kuang-Chao Chen, Taipei (TW)

(21) Appl. No.: 14/596,022

(22) Filed: Jan. 13, 2015

(51) Int. Cl. H01L 27/115; H01L 23/535; H01L 21/768; H01L 21/28

(52) U.S. Cl. CPC H01L 27/11582; H01L 21/28282; H01L 23/535; H01L 21/768

(57) ABSTRACT

Present example embodiments relate generally to semiconductor devices and methods of fabricating a semiconductor device comprising providing a substrate and forming a plurality of layers over the substrate. The plurality of layers comprise alternating first composition material layers and second composition material layers. The method further comprises forming an elongated post. The post extends from at least the top surface of the substrate.

### BACKGROUND

The present disclosure relates generally to semiconductor devices, and more specifically, relates to semiconductor structures, including three-dimensional (3D) gate-all-around (GAA) vertical gate (VG) structures in semiconductor devices, and methods of fabricating such semiconductor structures and devices.

There is an ever growing need by semiconductor device manufacturers to further shrink the critical dimensions of semiconductor structures and devices, to achieve greater storage capacity in smaller areas, and to do so at lower costs per bit. Three-dimensional (3D) semiconductor devices using, for example, thin film transistor (TFT) techniques, charge trapping memory techniques, and cross-point array techniques, have been increasingly applied to achieve the above needs by semiconductor manufacturers. Recent developments in semiconductor technology have included the fabrication of vertical structures in the form of 3D vertical channel (VC) NAND structures or 3D vertical gate (VG) NAND structures.

### BRIEF SUMMARY

Despite recent developments in the fabrication of semiconductor devices, it is recognized in the present disclosure that one or more problems may be encountered in fabricated three-dimensional (3D) semiconductor devices. For example, the formation of the various layers and structures of 3D vertical channel (VC) structures generally requires a relatively large footprint (or area). Furthermore, such fabricated 3D VC structures often encounter reliability problems and undesirable variations in performance. In respect to 3D VG structures, although 3D VG structures generally require smaller footprints (or areas) as compared to 3D VC structures, the reliable fabrication, including patterning and etching of the vertical gates of such devices and fabricating such devices free of deformation, defects, and/or bending, is oftentimes difficult to achieve.

Present example embodiments relate generally to semiconductor devices and methods of fabricating semiconductor devices that address one or more problems in fabricated semiconductor devices, including those described above and in the present disclosure.

In an exemplary embodiment, a method of fabricating a semiconductor device is described in the present disclosure comprising providing a substrate and forming a plurality of layers over the substrate. The plurality of layers comprise alternating first composition material layers and second composition material layers. The method further comprises forming an elongated post. The post extends from at least the top surface of the substrate.

In another exemplary embodiment, a semiconductor structure is described in the present disclosure. The semiconductor structure comprises a three-dimensional vertical gate structure having bit lines and word lines formed over a substrate. The semiconductor structure further comprises a plurality of elongated posts extending from at least a top surface of the substrate. The plurality of elongated posts are formed adjacent to the three-dimensional vertical gate structure.

### BRIEF DESCRIPTION OF THE DRAWINGS

For a more complete understanding of the present disclosure, example embodiments, and their advantages, reference is now made to the following description taken in conjunction with the accompanying drawings, in which like reference numbers indicate like features, and:

FIG. 1A is an example illustration of a two-dimensional horizontal channel device;

FIG. 1B is an example conceptual illustration of re-orienting a two-dimensional horizontal channel device from a horizontal orientation to a vertical orientation;

FIG. 1C is an example illustration of a three-dimensional vertical channel device;

FIG. 2A is an example illustration of a two-dimensional horizontal channel device;

FIG. 2B is an example conceptual illustration of re-configuring a two-dimensional horizontal channel device to vertically extend the gates;

FIG. 2C is an example illustration of a three-dimensional vertical gate device;

FIG. 3A is an example conceptual illustration of a footprint required for a three-dimensional vertical channel device;

FIG. 3B is an example conceptual illustration of a footprint required for a three-dimensional vertical gate device;

FIG. 4 is an example image illustrating a distortion, deformation, and/or bending of portions of vertical structures in three-dimensional devices;

FIG. 5 is an example embodiment of a method of fabricating a three dimensional semiconductor device;

FIG. 6A is a cross-sectional view of an example embodiment of alternating insulative material layers and conductive material layers formed over a substrate;

FIG. 6B is a top view of an example embodiment of identifying bit line and word line locations;

FIG. 7A is a side view of an example embodiment of a semiconductor device;

FIG. 7B is a top view of an example embodiment of a semiconductor device;

FIG. 7C is a perspective view of an example embodiment of a semiconductor device;

FIG. 8A is a side view of an example embodiment of a semiconductor device;

FIG. 8B is a perspective view of an example embodiment of a semiconductor device;

FIG. 9A is a perspective view of an example embodiment of a semiconductor device having a top buttress;

FIG. 9B is a top view of an example embodiment of a semiconductor device having a top buttress;

FIG. 9C is a top view of another example embodiment of a semiconductor device having a top buttress;

FIG. 9D is a top view of another example embodiment of a semiconductor device having a top buttress;

FIGS. 10A-L are illustrative views of an example embodiment of a method of fabricating an example embodiment of a semiconductor device;

FIGS. 11A-J are illustrative views of another example embodiment of a method of fabricating an example embodiment of a semiconductor device; and

FIGS. 12A-D are illustrative views of another example embodiment of a method of fabricating an example embodiment of a semiconductor device.

Although similar reference numbers may be used to refer to similar elements in the figures for convenience, it can be appreciated that each of the various example embodiments may be considered to be distinct variations.

### DETAILED DESCRIPTION

Example embodiments will now be described with reference to the accompanying drawings, which form a part of the present disclosure, and which illustrate example embodiments which may be practiced. As used in the present disclosure and the appended claims, the terms “example embodiment,” “exemplary embodiment,” and “present embodiment” do not necessarily refer to a single embodiment, although they may, and various example embodiments may be readily combined and/or interchanged without departing from the scope or spirit of example embodiments. Furthermore, the terminology as used in the present disclosure and the appended claims is for the purpose of describing example embodiments only and is not intended to be limitations. In this respect, as used in the present disclosure and the appended claims, the term “in” may include “in” and “on,” and the terms “a,” “an” and “the” may include singular and plural references. Furthermore, as used in the present disclosure and the appended claims, the term “by” may also mean “from,” depending on the context. Furthermore, as used in the present disclosure and the appended claims, the term “if” may also mean “when” or “upon,” depending on the context. Furthermore, as used in the present disclosure and the appended claims, the words “and/or” may refer to and encompass any and all possible combinations of one or more of the associated listed items.

Despite recent developments in the fabrication of semiconductor devices, it is recognized in the present disclosure that one or more problems may be encountered in the fabrication of three-dimensional (3D) semiconductor devices, and in the fabricated three-dimensional (3D) semiconductor devices themselves.

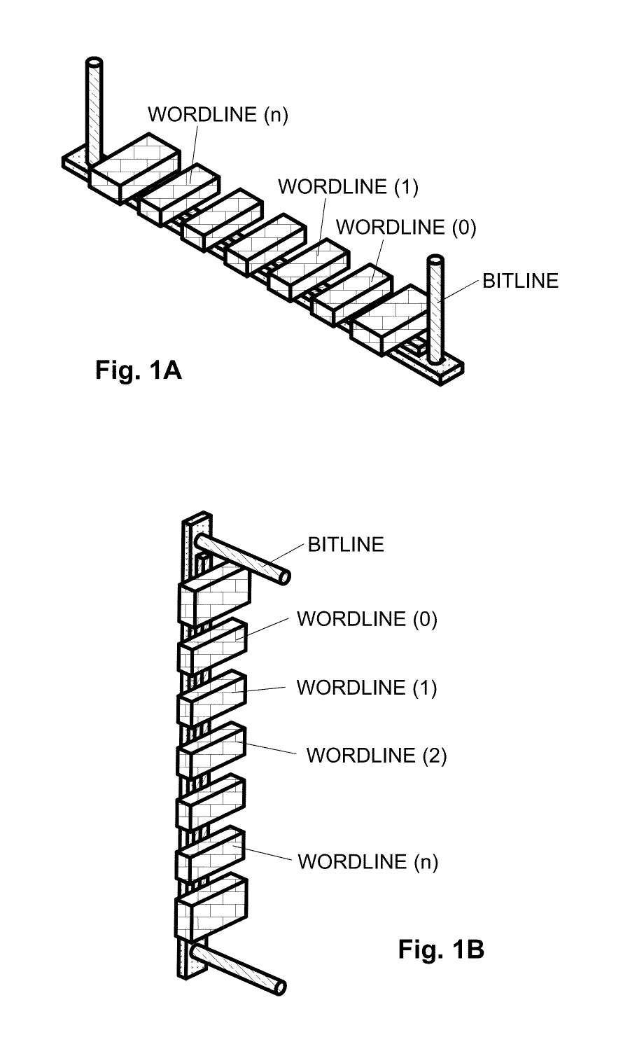

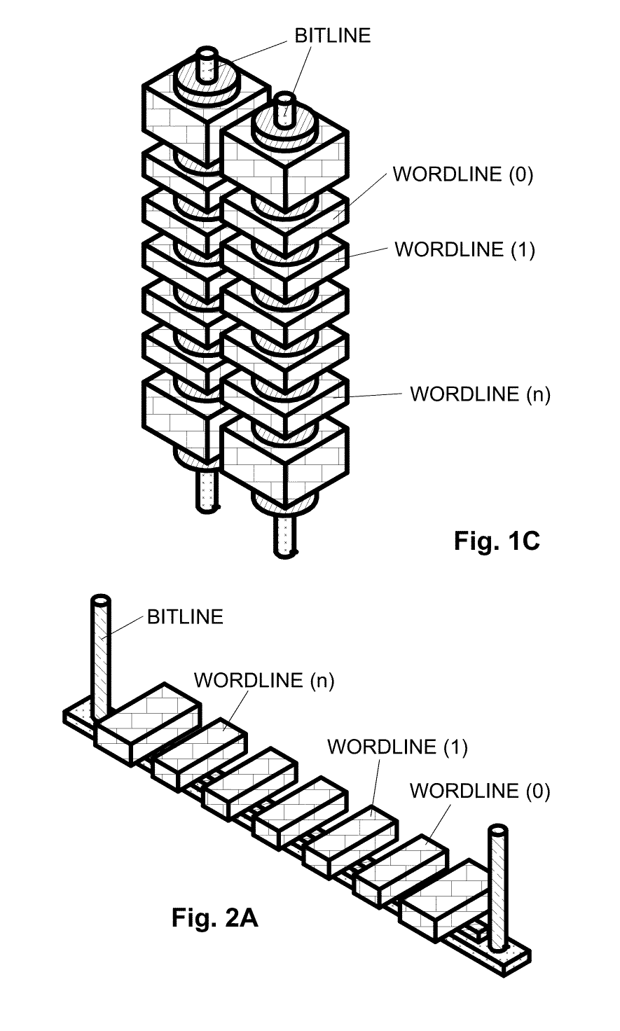

FIGS. 1A-C provide an example conceptual illustration of how a two-dimensional (2D) horizontal channel device relates to a 3D vertical channel (VC) device. As illustrated in FIGS. 1A and 1B, fabrication of a 3D VC device may conceptually be seen as first re-orienting a 2D horizontal channel device (FIG. 1A) from a horizontal orientation to a vertical orientation (FIG. 1B). Thereafter, a gate-all-around (GAA) structure may be formed (FIG. 1C illustrates 2 bit-line structures). In respect to 3D VC structures, the formation of the various layers and structures of the 3D VC structures generally requires a relatively large footprint (or area). Furthermore, such 3D VC structures often encounter problems pertaining to reliability and undesirable variations in performance, as well as deformations, defects, and/or bending of the vertical structures.

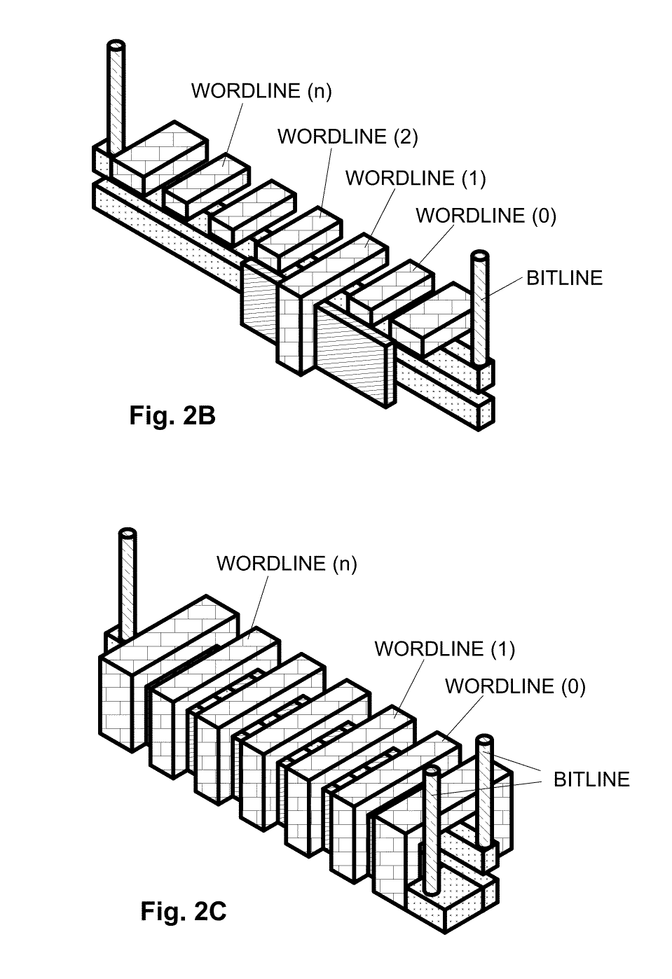

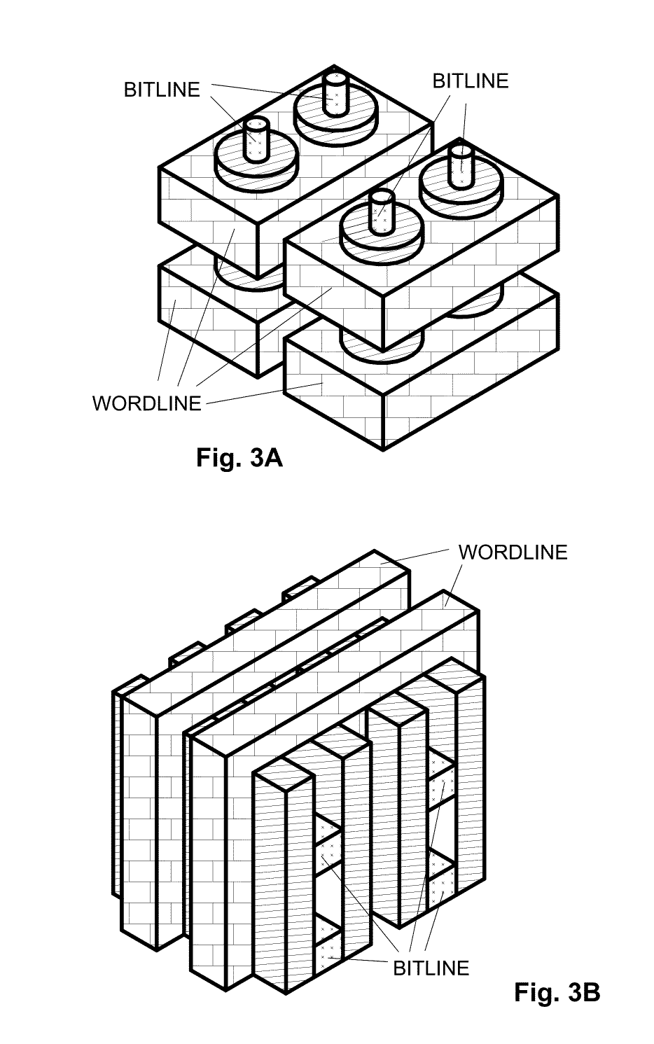

Recent developments have led to the introduction and development of 3D vertical gate (VG) structures, including 3D gate-all-around (GAA) VG structures. In general, a 3D VG structure requires relatively smaller footprints (or areas), as compared to 3D VC structures. FIGS. 2A-C provide an example conceptual illustration of how a 2D horizontal channel device relates to a 3D VG structure. As illustrated in FIGS. 2A and 2B, a 2D horizontal channel device (FIG. 2A) may be conceptually re-configured (FIGS. 2B and 2C) so as to vertically extend the gates. As shown in the comparative examples of FIGS. 3A-B, whereas a 3D VC device (conceptually illustrated in FIG. 3A) requires a footprint spanning along two axes (illustrated as X and Y axes), a 3D VG device (conceptually illustrated in FIG. 3B) merely occupies a footprint spanning along only one axis (illustrated as X axis).

Although 3D VG structures generally achieve smaller footprints as compared to 3D VC structures, semiconductor manufacturers oftentimes encounter difficulty in reliably fabricating 3D VG structures, including achieving reliable patterning and etching of the vertical gates of such devices and fabricating such devices free of deformations, defects, and/or bending of the vertical structures thereof. For example, due to the high aspect ratio requirements in such semiconductor devices, etching (especially near the bottom layers of the structures) is generally difficult to perform and oftentimes results in undesirable portions (hereinafter called “stringers”) to remain and/or form along the sidewall(s) and/or bottom portions of the semiconductor devices. Such stringers, when undesirably formed, may cause, among other things, bridging effects between layers and/or structures, such as between consecutive word lines, and may result in undesirable paths and/or leakage in the fabricated semiconductor device.

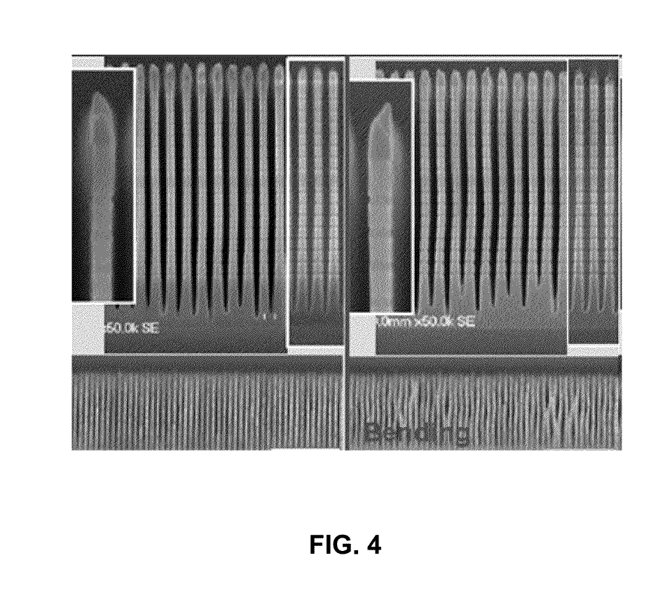

Another problem encountered in the fabrication of 3D vertical structures, such as 3D VC structures and 3D VG structures, pertains to the oftentimes encountered deformation, distortion, and/or bending in one or more portions of one or more vertical structures of the 3D VG structure. FIG. 4 illustrates an example of such a problem occurring in vertical structures of 3D VG structures.

Semiconductor devices and structures, including three-dimensional (3D) gate-all-around (GAA) vertical gate (VG) devices and structures, and methods of fabricating such semiconductor devices and structures are described in the present disclosure for addressing one or more problems encountered in semiconductor devices and structures, including those described above and herein. It is to be understood in the present disclosure that the principles described herein can be applied outside the context of NAND-type and NOR-type devices, including floating gate memory devices, charge trapping memory devices, non-volatile memory devices, and/or embedded memory devices.

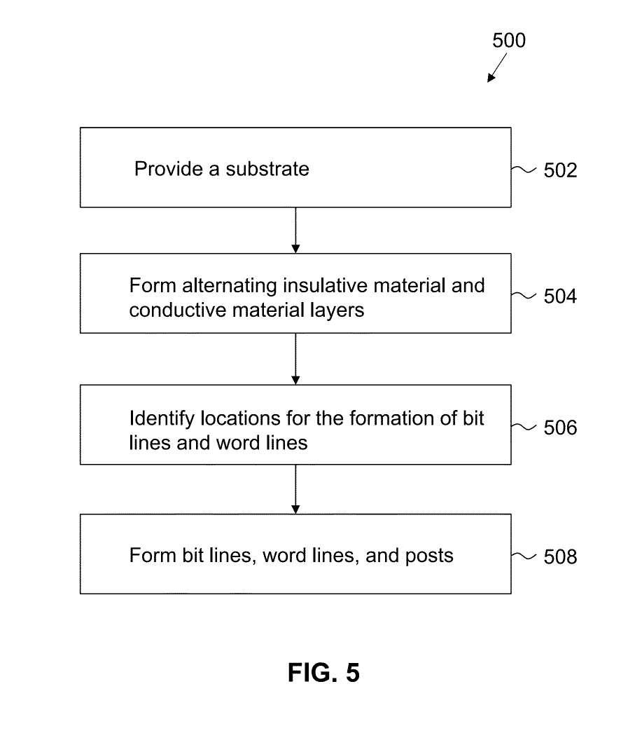

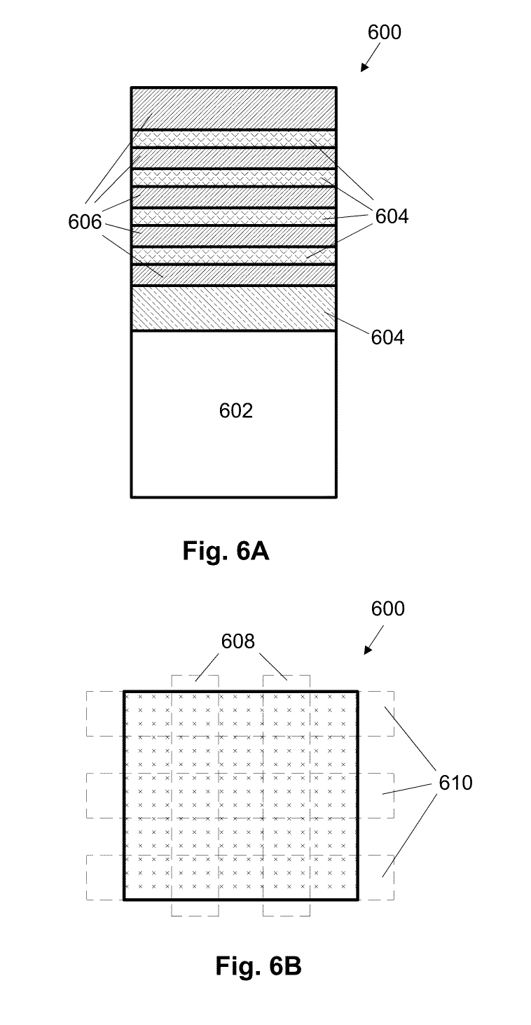

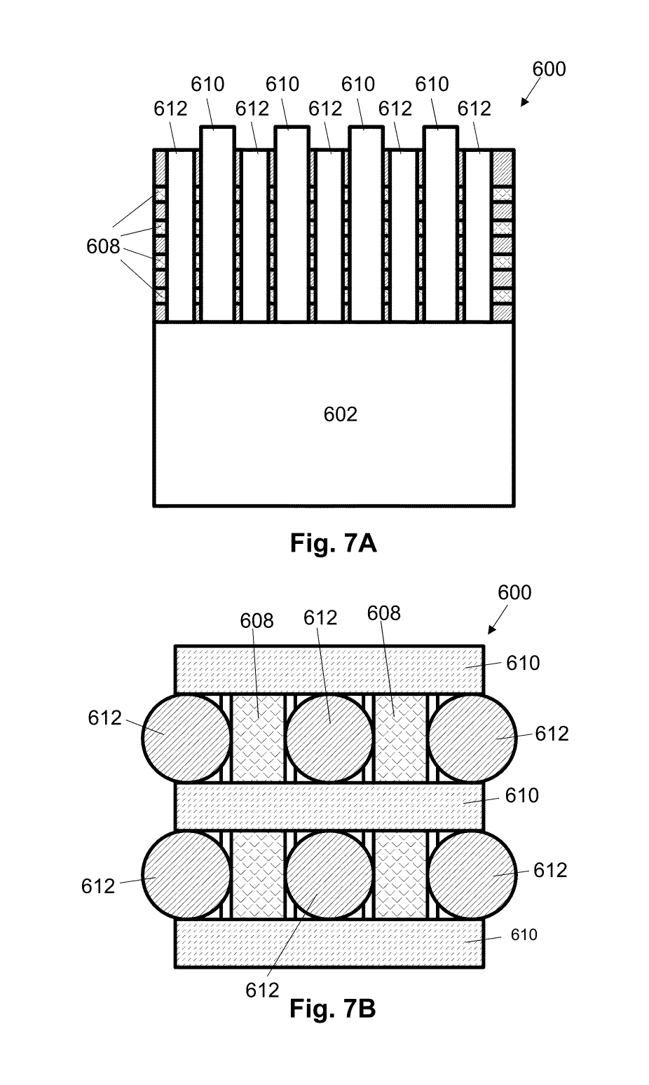

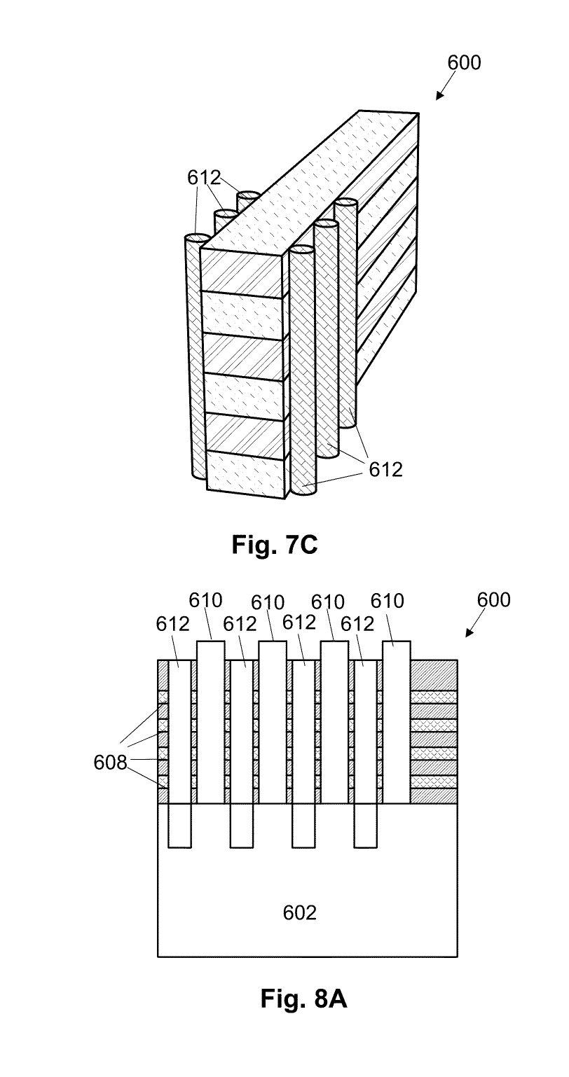

Example embodiments of methods for fabricating example embodiments of semiconductor devices, such as 3D VG structures, are depicted in FIGS. 5-12. As illustrated in the sequence of actions of FIG. 5, an example embodiment of a method 500 may include providing a substrate at action 502. An example embodiment of a method 500 may further include forming a plurality of alternating insulative material and conductive material layers over the substrate at action 504. A cross-sectional view of an example embodiment of alternating insulative material layers 604 and conductive material layers 606 formed over a substrate 602 is illustrated in FIG. 6A. The insulative materials may include oxides, and the like, and the conductive materials may include polysilicon, and the like. An example embodiment of a method 500 may further include identifying bit line and word line locations at action 506. A top view of an example embodiment of identifying bit line 608 and word line 610 locations is illustrated in FIG. 6B. An example embodiment of a method 500 may further include forming bit lines, word lines, and elongated posts at action 508. Example embodiments of a semiconductor device and/or structure comprising bit lines 608, word lines 610, and elongated posts 612 are illustrated in at least FIGS. 7-9. It is recognized in the present disclosure that present example embodiments, including one or more elongated posts formed on one or both sides of vertical structures of a semiconductor device, are operable to prevent and/or significantly eliminate the occurrence of deformation, distortion, and/or bending in the vertical structures of the semiconductor device. In other words, the elongated posts may be operable to provide support for the vertical structures of the semiconductor device so as to prevent such undesirable problems to occur during fabrication of the semiconductor device and/or in the finished semiconductor device product. Furthermore, example embodiments of the elongated posts may provide reductions in or absence of the occurrences of stringers and/or deformities, defects, and/or bending of the vertical structures in the semiconductor devices.

Example embodiments of a semiconductor device, such as a 3D VG device, may be fabricated according to one or more of the above actions, may also include additional actions, may be performable in different sequences, and/or one or more of the actions may be combinable into a single action or divided into two or more actions. Semiconductor devices other than NAND-type and NOR-type devices are also contemplated in example embodiments without departing from the teachings of the present disclosure. These actions and semiconductor devices will now be described with references to FIGS. 5-12.

(1) Providing a Substrate (e.g., Action 502).

Substrates 602 appropriate for use in semiconductor devices and structures may be obtained by any one or more manufacturing methods, such as pressing methods, float methods, down-drawn methods, redrawing methods, fusion methods, and/or the like.

(2) Forming a Plurality of Alternating Insulative Material Layers and Conductive Material Layers (e.g., Action 504).

A substrate 602, such as one obtained from the above action 502, may be provided with alternating insulative material layers 604 and conductive material layers 606 thereon (e.g., action 504), as illustrated in the cross-sectional view of FIG. 6A. The insulative materials may include oxides, and the like, and the conductive materials may include polysilicon, and the like. The thickness of each of the conductive layers 506 may be about 200 Angstroms. It is recognized herein that the thickness of each of the conductive layers 606 may be about 100-300 Angstroms in example embodiments. The thickness of each of the insulative layers 604 may be about 800 Angstroms. It is recognized herein that the thickness of each of the insulative layers 508 may be about 100-1000 Angstroms in example embodiments.

(3) Identifying Word Line and Bit Line Locations (e.g., Action 506).

A substrate 602 having alternating insulative material layers 604 and conductive material layers 606 formed thereon may be subjected to an identification (or planning or designing) process whereby bit line locations 608 and word line 610 locations are identified (or planned or designed) for subsequent actions (as described below and herein), including the forming of bit lines 608, word lines 610, and posts 612. An example identification of bit line 608 and word line 610 locations is illustrated in the top view illustration of FIG. 6B.

(4) Forming Bit Lines, Word Lines, and Elongated Posts (e.g., Action 508).

The formation of bit lines 608, word lines 610, and elongated posts (or posts) 612 may be performed in one or more of a plurality of ways in example embodiments. FIGS. 7-9 provide illustrations of example actions that may be employed for the fabrication of example embodiments of semiconductor devices. These example embodiments are now described below.

### (4A) First Example Embodiment

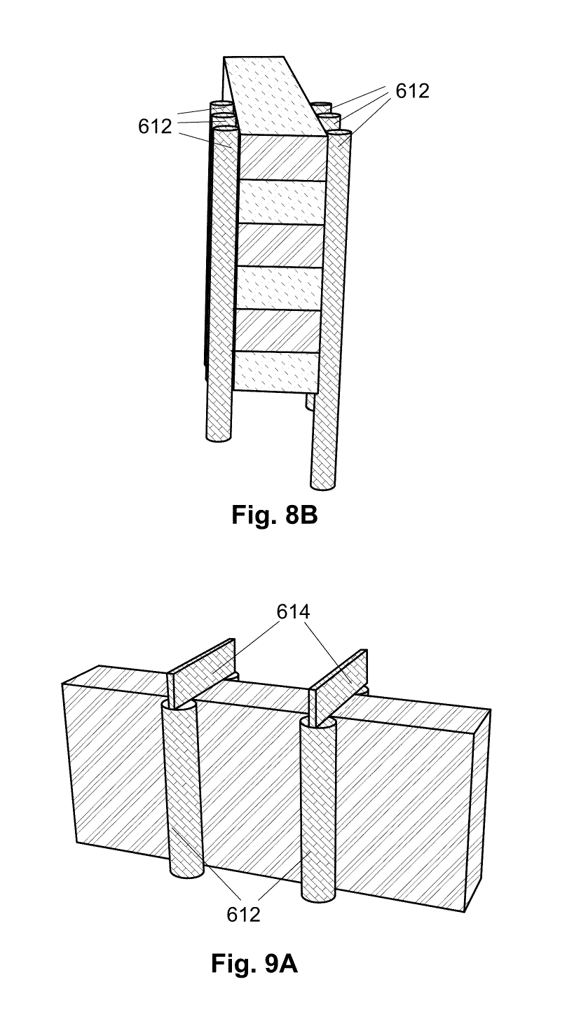

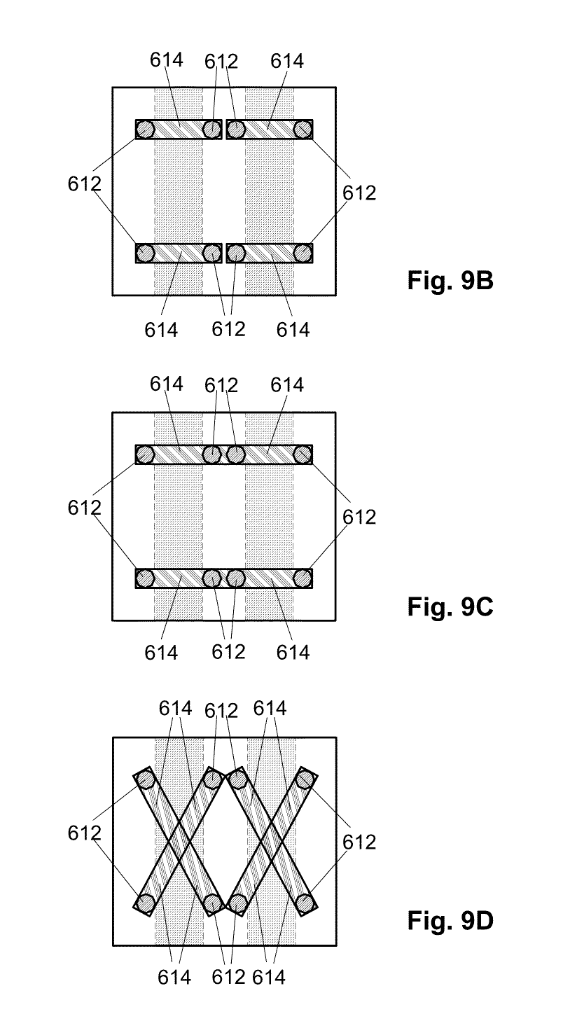

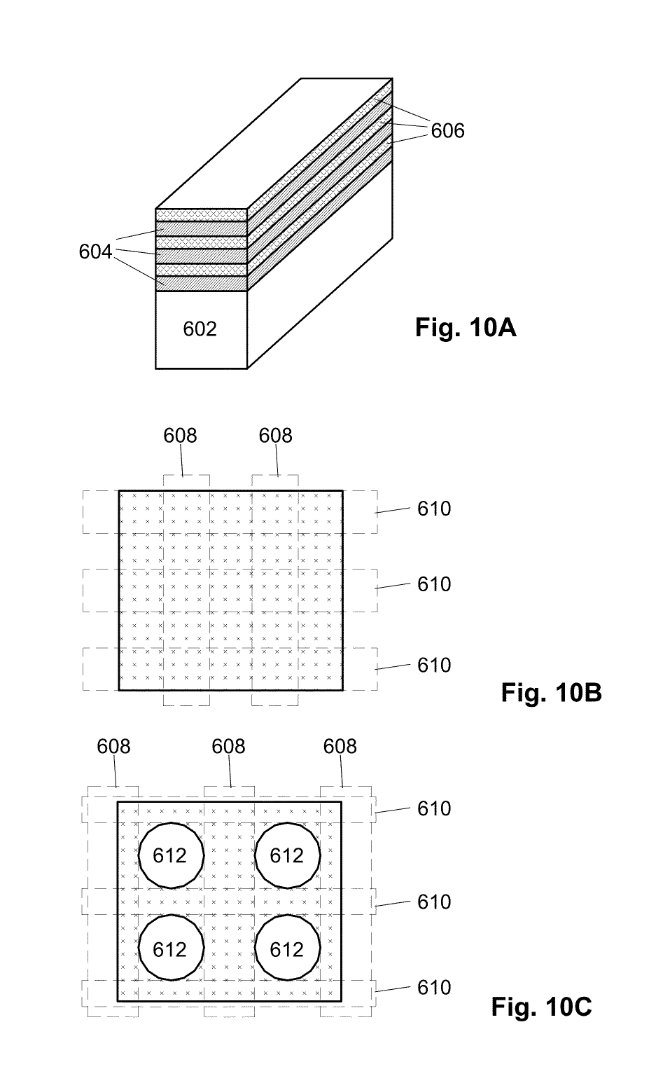

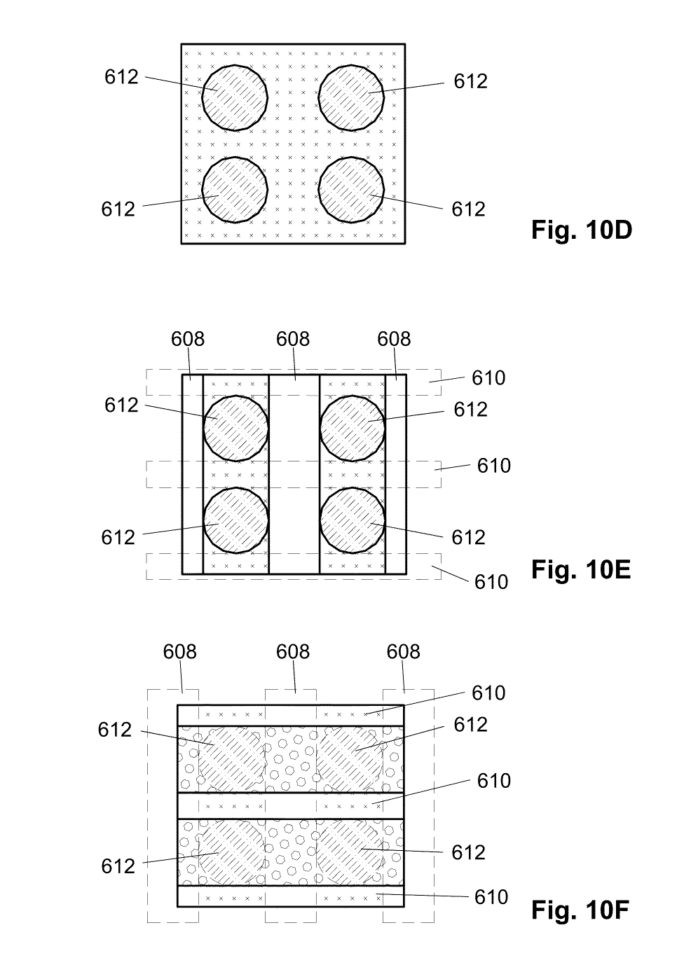

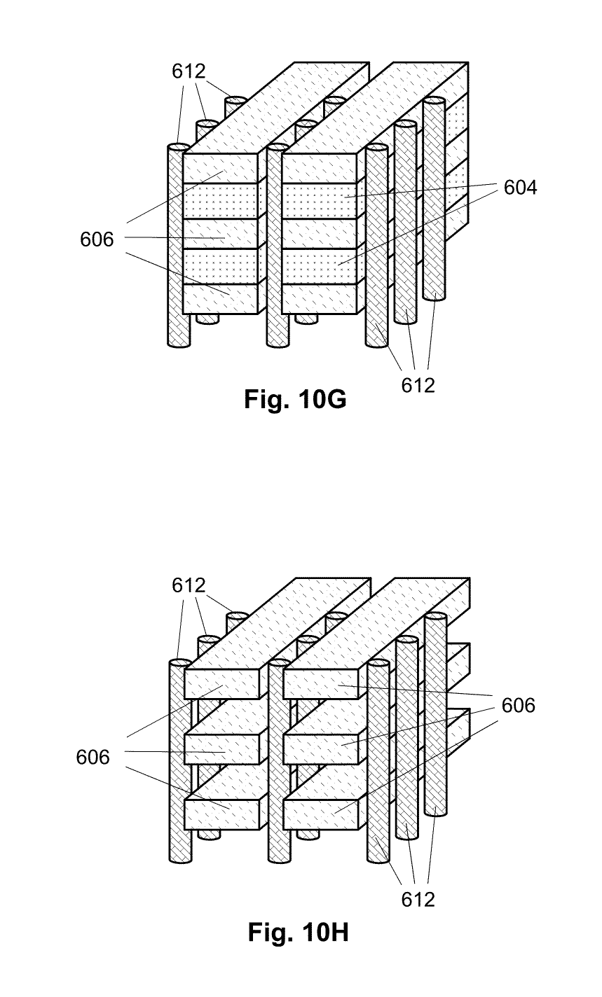

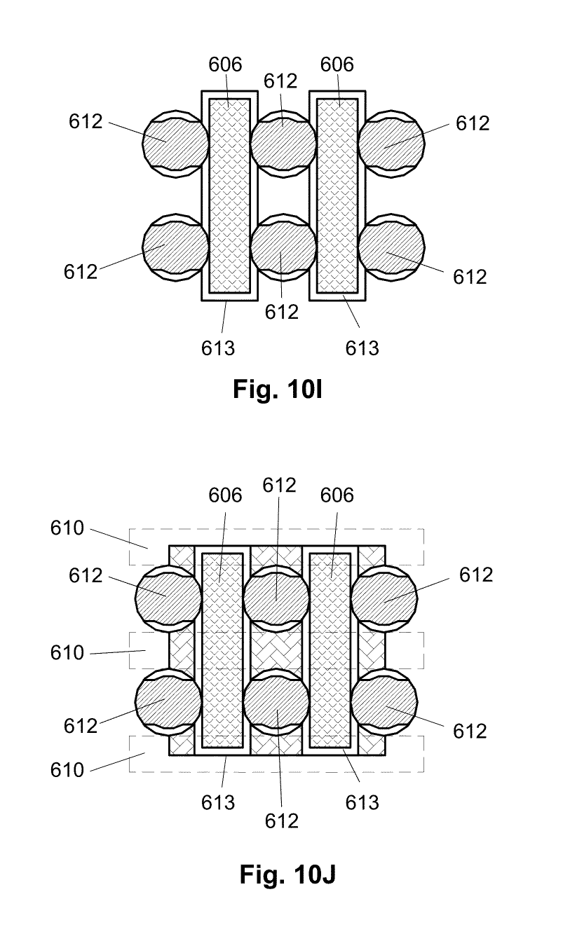

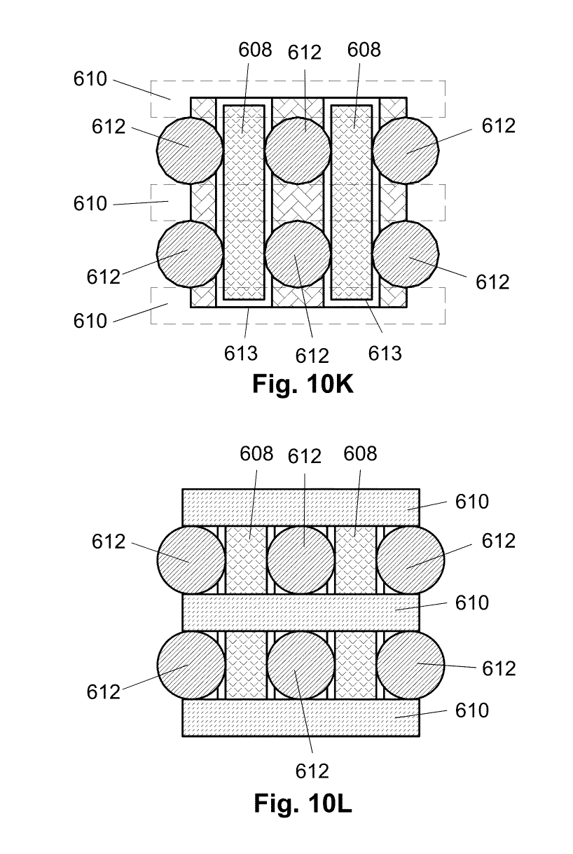

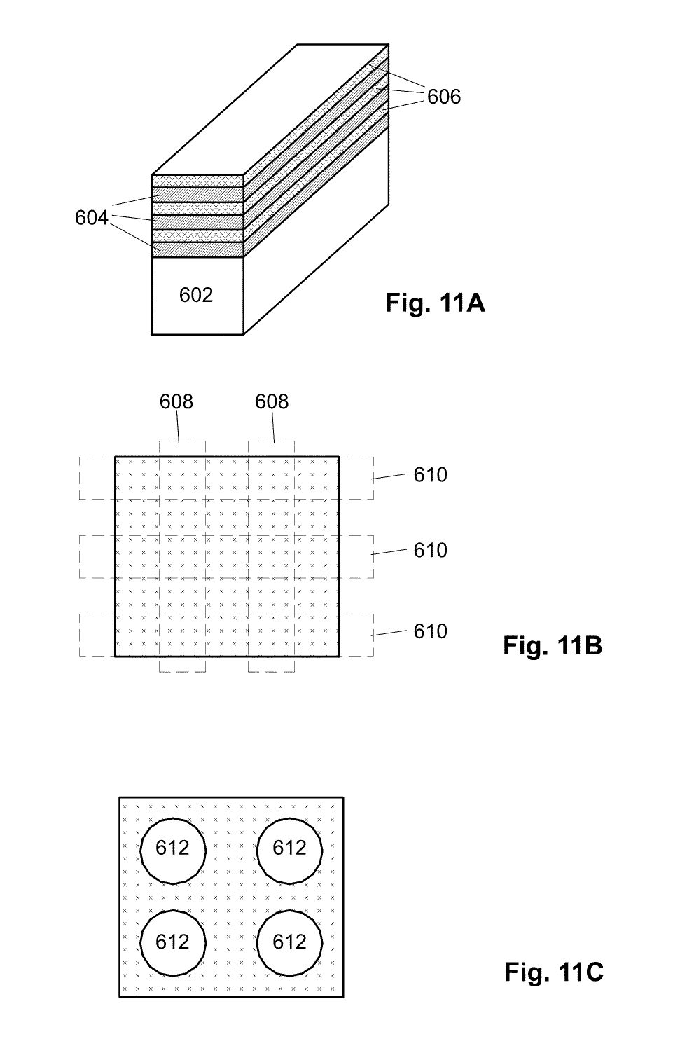

FIGS. 10A-L provide illustrations of example actions for fabricating example embodiments of semiconductor devices having elongated posts 612 (such as the semiconductor devices illustrated in FIG. 7C, FIGS. 8A-B, and FIGS. 9A-D).

As illustrated in the perspective view illustration of FIG. 10A and the cross-sectional view illustration of FIG. 6A, a substrate 602 may be provided with alternating insulative material layers 604 and conductive material layers 606 thereon (e.g., action 504). The insulative materials may include oxides, and the like, and the conductive materials may include polysilicon, and the like. The insulative material layers 604 may be about 50-70 nm in thickness and the conductive material layers 606 may be about 10-30 nm in thickness. Bit line locations 608 and word line 610 locations may then be identified for the stack (e.g., action 506), as illustrated in the top view illustration of FIG. 10B and FIG. 6B. The bit line pitch may be about 80-160 nm and the word line pitch may be about 80-160 nm in example embodiments.

One or more elongated holes 612′ may then be formed through the plurality of alternating insulative material layers 604 and conductive material layers 606 in selected areas that are adjacent to the identified bit line locations 608, as illustrated in the top view illustrations of FIG. 10C. For example, the holes 612′ may have a diameter of about 5-80 nm. These one or more elongated holes 612′ are formed so as to be later filled (as later illustrated in FIGS. 10D and 10K) to form the elongated posts 612. In this regard, consideration may be taken regarding identifying the word line locations 610 since the holes 612′ may preferably be formed in anti-word line areas (or areas identified as not being word line locations 610). In example embodiments, a portion (or side) of a hole 612′ may be formed within a portion (or side) of an identified bit line location 608 and/or word line location 610.

The holes 612′ may be formed extending from a top surface of the substrate 602, such as in the example embodiments illustrated in FIGS. 7-C. In such an embodiment, the later-formed elongated posts 612 will have a base extending from the top surface of the substrate 602. Alternatively or in addition, some or all of the holes 612′ may be formed extending from below the top surface of the substrate 602, such as in the example embodiments illustrated in FIGS. 8A and 8B. In such an embodiment, the later-formed elongated posts 612 will have a base extending from below the top surface of the substrate 602. For example, the holes 612′ (and corresponding later-formed elongated posts 612) may be formed 120-240 nm below the top surface of the substrate 602. In example embodiments, the selected areas for the formation of the holes 612′ may include areas between each identified word line location 610, areas before the first and/or after the last identified word line location, and/or areas between only some identified word line locations 610.

A deposition process may be performed to fill the holes 612′ and form the elongated posts 612, as illustrated in the top view illustration of FIG. 10D. In an example embodiment, the holes 612′ may be filled with a nitride material, such as silicon nitride, so as to form elongated posts. In this example embodiment, the elongated posts are preliminary elongated posts that will be replaced in a later action (as illustrated in FIG. 10K and described below).

The method may further include the removal of a portion of the plurality of alternating insulative material layers 604 and conductive material layers 606 in those areas that are not identified as being bit line locations 608, as illustrated in the top view illustration of FIG. 10E. It should be noted that the material deposited into the holes 612′ (as performed in the action illustrated in FIG. 10D) may not be removed in the previously stated removal action of FIG. 10E.

A patterning process may be performed along the identified word line locations 610 so as to ensure the filled holes 612′ (i.e., the elongated posts) are sufficiently adjacent to and/or in contact with the side walls of the bit line locations 608, as illustrated in FIGS. 10F and 10G.

Insulative material may also be removed from the insulative material layers 604 remaining after performing the previous actions, as illustrated in the perspective view illustration of FIG. 10H. The remaining conductive material layers 606 can be conceptually viewed as being floating or suspending since the insulative material have been removed from the insulative material layers 604. In this regard, the filled holes 612′ (i.e., the elongated posts) may be operable to provide support to the remaining conductive material layers 606. It is to be understood in the present disclosure that the material deposited in the holes 612′ may not be removed in the previously stated removal action of FIG. 10H. This is achievable by, among other ways, selecting the fill material in the holes 612′ to be different from the insulative material in the insulative material layers 604.

A charge storage structure 613 may be formed adjacent to and/or surrounding at least a portion of the remaining conductive material layers 606, as illustrated in the top view illustration of FIG. 10I. The charge storage structure 613 may be formed by, for example, a deposition of an oxide nitride oxide (ONO) layer. Prior to the formation of the charge storage structure 613, a rounding process may be performed to round the remaining conductive material layers 606. In example embodiments, the charge storage structure 613 may be formed extending vertically from the top surface of the substrate 602 or from a certain height above the top surface of the substrate 602.

As illustrated in the top view illustration of FIG. 10J, a deposition process may be performed so as to deposit a conductive material in the identified word line locations 610. In this regard, the conductive material may be deposited in at least a portion of the areas in respect of which the plurality of alternating insulative material 604 and/or conductive material 606 layers were removed (as performed in the action illustrated in FIG. 10E). It is to be understood in the present disclosure that the conductive material deposited (as illustrated in FIG. 10J) may be deposited adjacently to the formed charge storage structure (as performed in the action illustrated in FIG. 10I).

In example embodiments, the material filled in the holes 612′ (as performed in the action illustrated in FIG. 10D) that form the elongated posts 612 may be removed (such as in example embodiments wherein the fill material is different from the insulative material in the insulative material layers 604), and the remaining holes 612′ may be re-filled with an insulative material so as to re-form the elongated posts 612. The aforementioned actions are illustrated in the top view illustration of FIG. 10K, which also illustrates the formed elongated posts 612. The base of one or more of the elongated posts 612 may extend from the top surface of the substrate 602 or from below the top surface of the substrate 602. The top (or opposite end to the base) of one or more of the elongated posts 612 may extend to the top surface of the semiconductor structure or above or below the top surface of the semiconductor structure in example embodiments. It is recognized in the present disclosure that example embodiments of the elongated posts are operable to improve reliability of fabricated semiconductor devices by preventing and/or significantly eliminating the occurrence of deformation, distortion, and/or bending in the vertical structures, including the bit lines and word lines, of the semiconductor device. In other words, the elongated posts may be operable to provide improved support for fabricated vertical structures (including bit lines and word lines) of the semiconductor device so as to prevent such undesirable problems from occurring during fabrication of the semiconductor device and/or in the finished semiconductor device product. Furthermore, example embodiments of the elongated posts may provide reductions in or absence of the occurrences of stringers and/or deformities, defects, and/or bending of the vertical structures in the semiconductor devices.

As illustrated in FIG. 10L, the word lines 610 may then be formed and connected to the conductive material (that was deposited in the action illustrated in FIG. 10J). FIG. 10L also illustrates the formed elongated posts 612 and the bit lines 608.

### (4B) Second Example Embodiment

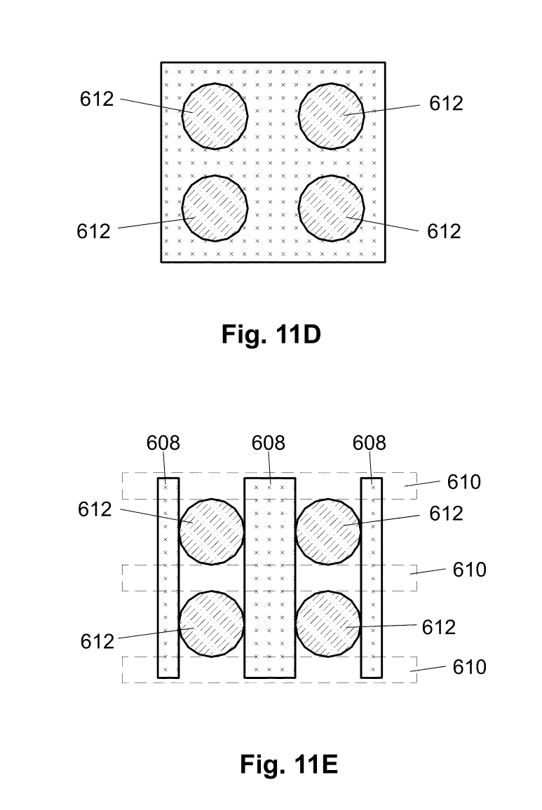

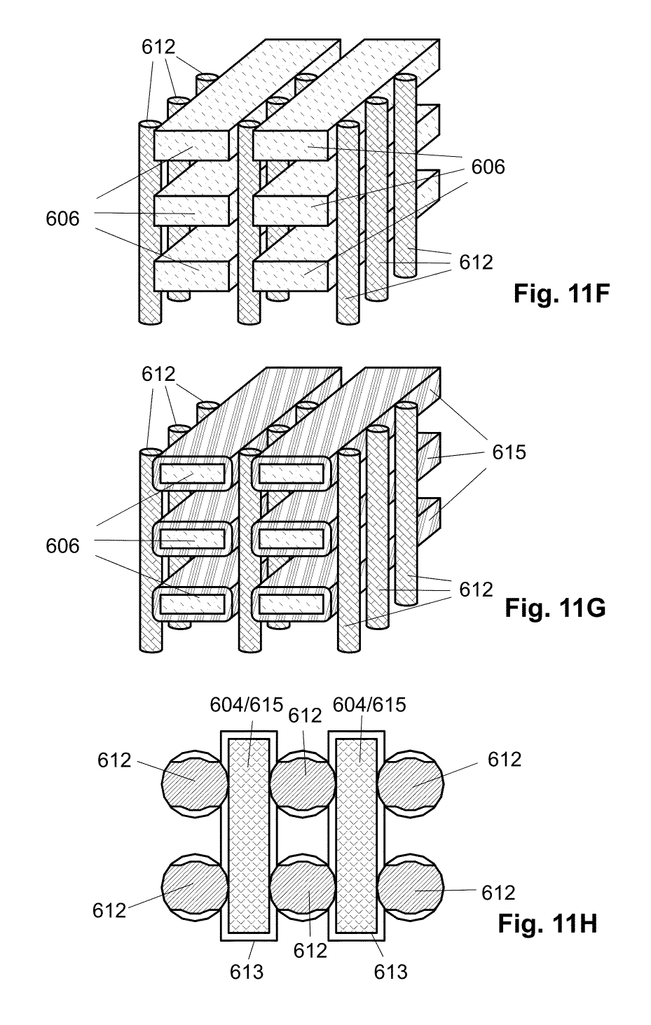

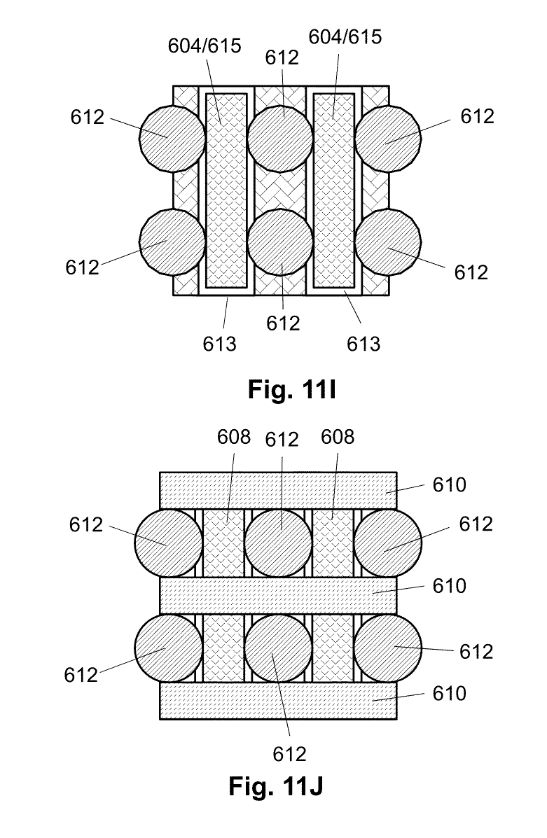

FIGS. 11A-J provide illustrations of example actions for fabricating example embodiments of semiconductor devices having elongated posts 612 (such as the semiconductor devices illustrated in FIG. 7C, FIGS. 8A-B, and FIGS. 9A-D).

As illustrated in the perspective view illustration of FIG. 11A and the cross-sectional view illustration of FIG. 6A, a substrate 602 may be provided with alternating insulative material layers 604 and conductive material layers 606 thereon (e.g., action 504). The insulative material layers 604 may be about 50-70 nm in thickness and the conductive material layers 606 may be about 10-30 nm in thickness. Bit line 608 and word line 610 locations may then be identified for the stack (e.g., action 506), as illustrated in the top view illustration of FIG. 11B and FIG. 6B. The bit line pitch may be about 80-160 nm and the word line pitch may be about 80-160 nm in example embodiments.

One or more elongated holes 612′ may then be formed through the plurality of alternating insulative material layers 604 and conductive material layers 606 in selected areas that are adjacent to the identified bit line locations 608, as illustrated in the top view illustrations of FIG. 11C. For example, the holes 612′ may have a diameter of about [5-80] nm. These one or more elongated holes 612′ are formed so as to be later filled (as later illustrated in FIGS. 10D and 10K) to form the elongated posts 612. In this regard, consideration may be taken regarding identifying word line locations 610 since the holes 612′ may preferably be formed in anti-word line areas (or areas identified as not being word line locations 610). In example embodiments, a portion (or side) of a hole 612′ may be formed within a portion (or side) of an identified bit line location 608 and/or word line location 610.

The holes 612′ may be formed extending from the top surface of the substrate 602, such as in the example embodiments illustrated in FIGS. 7A-C. In such an embodiment, the later-formed elongated posts 612 will have a base extending from the top surface of the substrate 602. Alternatively or in addition, some or all of the holes 612′ may be formed extending from below the top surface of the substrate 602, such as in the example embodiments illustrated in FIGS. 8A and 8B. In such an embodiment, the later-formed elongated posts 612 will have a base extending from below the top surface of the substrate 602. For example, the holes 612′ (and corresponding later-formed elongated posts 612) may be formed 120-240 nm below the top surface of the substrate 602. In example embodiments, the selected areas for the formation of holes 612′ may include areas between each identified word line location 610, areas before the first and/or after the last identified word line location, and/or areas between only some identified word line locations 610.

A deposition process may be performed to fill the holes 612′ and form the elongated posts 612, as illustrated in the top view illustration of FIG. 11D. In an example embodiment, the elongated holes 612′ may be filled with an insulative material. For example, the insulative material may be the same, similar, or different material as the insulative material in the insulative material layers 604. The base of one or more of the elongated posts 612 may extend from the top surface of the substrate 602 or from below the top surface of the substrate 602. The top (or opposite end to the base) of one or more of the elongated posts 612 may extend to the top surface of the semiconductor structure or above or below the top surface of the semiconductor structure in example embodiments. It is recognized in the present disclosure that example embodiments of the elongated posts are operable to prevent and/or significantly eliminate the occurrence of deformation, distortion, and/or bending in the vertical structures, including the bit lines and word lines, of the semiconductor device. In other words, the elongated posts may be operable to provide improved support for fabricated vertical structures (including bit lines and word lines) of the semiconductor device so as to prevent such undesirable problems from occurring during fabrication of the semiconductor device and/or in the finished semiconductor device product. Furthermore, example embodiments of the elongated posts may provide reductions in or absence of the occurrences of stringers and/or deformities, defects, and/or bending of the vertical structures in the semiconductor devices.

The method may further include the removal of a portion of the plurality of alternating insulative material layers 604 and conductive material layers 606 in those areas that are not identified as the bit line locations 608, as illustrated in the top view illustration of FIG. 11E. It should be noted that the insulative material deposited into the holes 612′ may not be removed in the previously stated removal action of FIG. 11E.

The conductive material may also be removed from the conductive material layers 606 in the identified bit line locations 608 remaining after performing the previous actions, as illustrated in the perspective view illustration of FIG. 11F. The remaining insulative material layers 604 can be conceptually viewed as being floating or suspending since the conductive material have been removed from the conductive material layers 606. In this regard, the filled holes 612′ (i.e., the elongated posts 612) may be operable to provide support to the remaining conductive material layers 606. It is to be understood in the present disclosure that the insulative material deposited into the holes 612′ may not be removed in the previously stated removal action of FIG. 11F. This is achievable by, among other ways, selecting the fill material in the holes 612′ to be different from the conductive material in the conductive material layers 606.

A macaroni conductive deposition process, or the like, may be performed to form a macaroni conductive deposition layer 615, or the like, adjacent to and/or surrounding at least a portion of the remaining insulative material layers 604, as illustrated in the top view illustration of FIG. 11G.

A charge storage structure 613 may be formed adjacent to and/or surrounding at least a portion of the macaroni conductive deposition layers, as illustrated in the top view illustration of FIG. 11H. The charge storage structure may be formed by, for example, a deposition of an oxide nitride oxide (ONO) layer. In example embodiments, the charge storage structure may be formed extending vertically from the top surface of the substrate 602 or from a certain height above the top surface of the substrate 602.

As illustrated in the top view illustration of FIG. 11I, a deposition process may be performed so as to deposit a conductive material in the identified word line locations 610. In this regard, the conductive material may be deposited in at least a portion of the areas in respect of which the plurality of alternating insulative material 604 and/or conductive material 606 layers were removed (as performed in the action illustrated in FIG. 11E). It is to be understood in the present disclosure that the conductive material deposited (as illustrated in FIG. 11I) may be deposited at least adjacently to the formed charge storage structure (as performed in the action illustrated in FIG. 11H).

As illustrated in FIG. 11J, the word lines 610 may then be formed and connected to the conductive material (that was deposited in the action illustrated in FIG. 11I). FIG. 11J also illustrates the formed elongated posts 612 and the bit lines 608.

### (4C) Third Example Embodiment

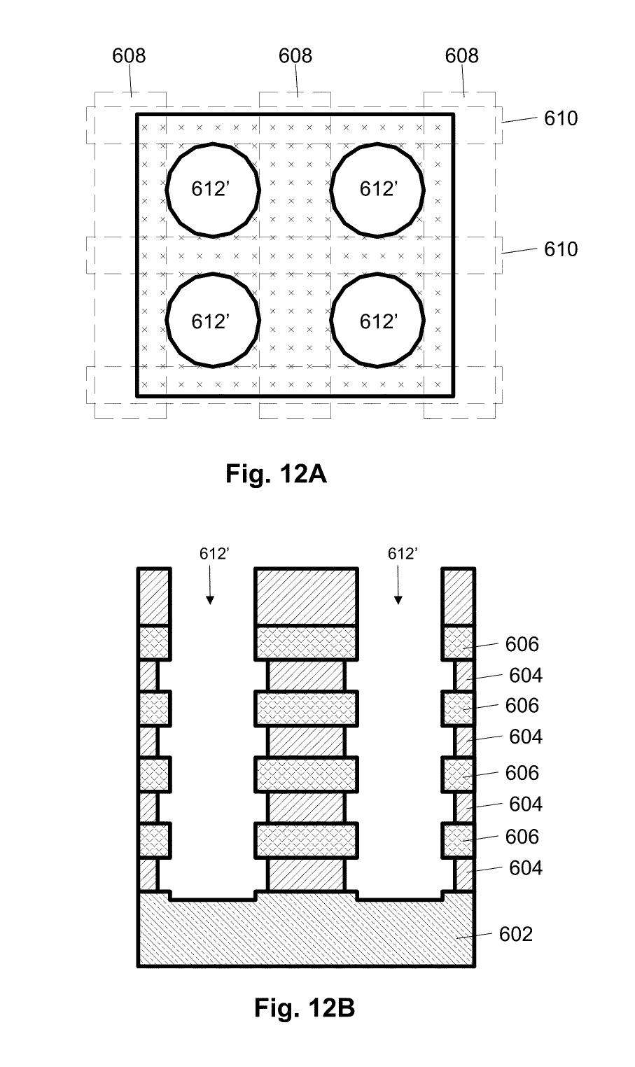

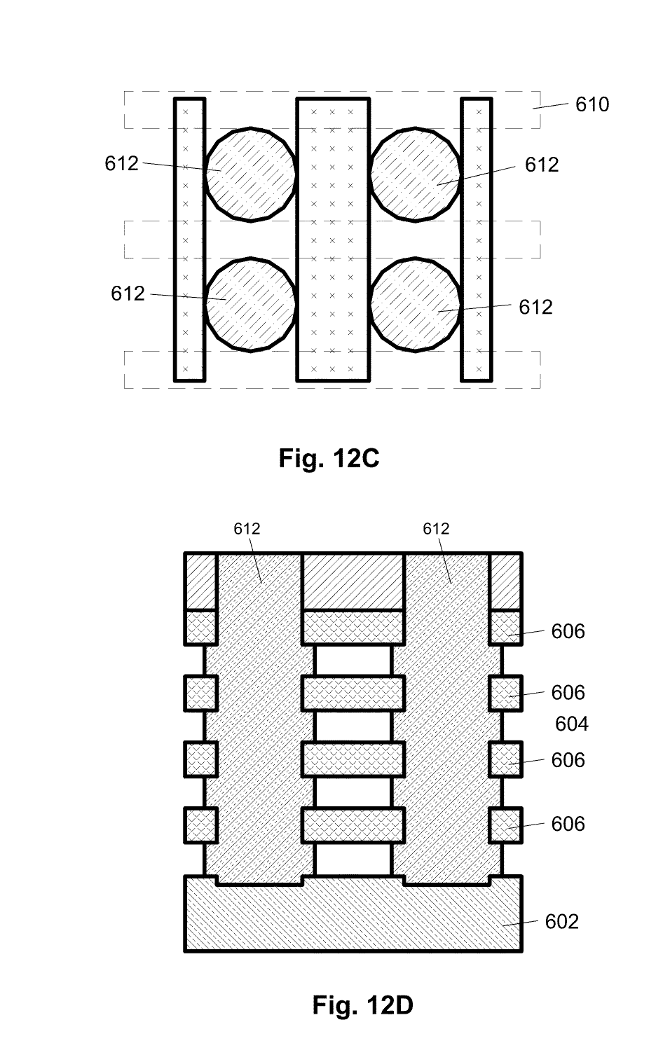

FIGS. 12A-B provide illustrations of additional example actions for fabricating example embodiments of semiconductor devices having elongated posts 612 (such as the semiconductor devices illustrated in FIG. 7C, FIGS. 8A-B, and FIGS. 9A-D). These additional actions may be performed in the example methods described above and herein and illustrated in FIGS. 10A-L and 11A-J.

A substrate 602 may be provided with alternating insulative material layers 604 and conductive material layers 606 thereon (e.g., action 504). Bit line 608 and word line 610 locations may then be identified (e.g., action 506), and one or more elongated holes 612′ may be formed through the plurality of alternating insulative material layers 604 and conductive material layers 606 in selected areas that are adjacent to the identified bit line locations 608. As illustrated in the top view illustration of FIG. 12A and the cross-sectional view illustration of FIG. 12B, example embodiments of the method may further comprise performing an isotropic etch, or the like, so as to remove a portion of insulative material from the insulative material layers 604. The portion of insulative material removed from the insulative material layers 604 may be a portion facing the formed hole 612′, as shown in FIG. 12B. It is recognized in the present disclosure that performing of the aforementioned action may provide additional advantages. For example, in the first example embodiment (as illustrated in FIGS. 10A-L), performing the filling of the holes 612′ and the filling of the removed portions of the insulative material layers 604 with a nitride material (or the like) effectively creates protruded portions into the insulative material layers 604, which provides for additional support (via the filled material in the removed portions of the insulative material layers 604) after performing the removing of the insulative material from the insulative material layers 604 (such as the actions illustrated in FIG. 10H). This is illustrated in the top view illustration of FIG. 12C and the cross-sectional view illustration of FIG. 12D. Similar advantages may be achievable for the second example embodiment (as illustrated in FIGS. 11A-J) by a similar additional action of removing a portion of the conductive material from the conductive material layers 606, which is performed after the action illustrated in FIG. 11C.

Example embodiments of semiconductor devices having elongated posts 612 fabricated using the above-mentioned example actions, including those illustrated in FIGS. 5-12, may exhibit improved support for fabricated vertical structures (including bit lines and word lines) of the semiconductor device, as well as reductions in or absence of the occurrences of stringers and/or deformities, defects, and/or bending of the vertical structures in the semiconductor devices.

An example embodiment of a semiconductor device may be further provided with a top buttress 614, or the like, operable to connect two or more formed elongated posts 612. FIG. 9A illustrates an example embodiment of such a top buttress 614 connecting a first elongated post 612 to a second elongated post 612b, the first elongated post 612a formed adjacent to a first side of the semiconductor device and the second elongated post 612b formed adjacent to a second side of the semiconductor device. FIG. 9B is a top view illustration of individual top buttresses 614, and FIG. 9C is a top view illustration of shared, unified, or integrated top buttresses 614. FIG. 9D is a top view illustration of another example embodiment of a top buttress 614.

It is to be understood in the present disclosure that the charge storage structure may include oxide-nitride-oxide, silicon-oxide-nitride-oxide-silicon (SONOS), or BE-SONOS structures, including those comprising a tunneling dielectric layer, a trapping layer, and a blocking oxide layer. The tunneling dielectric layer may comprise oxide, nitride, and oxide sub-layers and/or a composite of materials forming an inverted “U” shaped valence band under zero bias voltage; the trapping layer may comprise nitride; and the blocking oxide or gate layer may comprise oxide. The tunneling dielectric layer may further include a hole tunneling layer, a band offset layer, and an isolation layer. Other internal structures are also contemplated in this disclosure, including those for floating gate memory, charge trapping memory, NAND-type devices, semiconductor devices other than NAND-type devices, non-volative memory devices, and/or embedded memory devices.

While various embodiments in accordance with the disclosed principles have been described above, it should be understood that they have been presented by way of example only, and are not limiting. Thus, the breadth and scope of the example embodiments described in the present disclosure should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

For example, as referred to in the present disclosure, “forming” a layer, plurality of layers, plurality of alternating layers, multilayer, stack, and/or structure may include any method of creating the layer, multilayer, and/or structure, including depositing and the like. A “multilayer” may be one layer, structure, and/or stack comprising a plurality of internal layers and/or a plurality of layers, multilayers, structures, and/or stacks stacked or formed on or over one another. Internal structures may include any internal structure of a semiconductor device, including charge storage structures such as silicon-oxide-nitride-oxide-silicon (SONOS) or bandgap engineered silicon-oxide-nitride-oxide-silicon (BE-SONOS) structures comprising a tunneling dielectric layer, a trapping layer, and a blocking oxide layer.

Although one or more layers, multilayers, and/or structures may be described in the present disclosure as being “silicon,” “polysilicon,” “conductive,” “oxide,” and/or “insulative” layers, multilayers, and/or structures, it is to be understood that example embodiments may be applied for other materials and/or compositions of the layers, multilayers, and/or structures. Furthermore, such structures may be in the form of a crystalline structure and/or amorphous structure in example embodiments.

Furthermore, “patterning” of one or more layers, multilayers, and/or structures may include any method of creating a desired pattern on the one or more layers, multilayers, and/or structures, including performing a photolithography process by applying a photoresist mask (not shown) having pre-formed patterns and etching the layers, multilayers, and/or structures according to the pre-formed patterns on the photoresist mask.

“Stringers” formed, deposited, and/or remaining in and/or on material(s), layer(s), structure(s), and/or between materials, layers, and/or structures may include conductive material, insulative material, and materials having openings, bores, gaps, voids, cracks, holes, bubbles, and the like, and/or a mixture thereof. Furthermore, although the present disclosure describes example embodiments for addressing “stringers,” the claimed approaches described in the present disclosure may also be beneficially applicable to address and/or improve other performance-related problems and/or issues, including formation, shifting, changing in size, changing in shape, changing in composition, combining, dividing, and/or migrating of other types of imperfections in the semiconductor fabrication process.

“Elongated posts” or “posts” may be formed, filled, constructed, deposited, and/or structured using one or more of a plurality of materials, including insulative materials, conductive materials, nitrides, and the like, and a cross-section of the elongated posts may be formed in one or more of a plurality of shapes, including a circle, an oval, a square, a rectangle, a triangle, and/or a combination of geometric shapes.

It is to be understood in the present disclosure that the principles described can be applied outside the context of NAND-type devices described in exemplary embodiments, including NOR-type devices, other memory storage devices, floating gate memory devices, charge trapping memory devices, non-volatile memory devices, and/or embedded memory devices.

Various terms used herein have special meanings within the present technical field. Whether a particular term should be construed as such a “term of art” depends on the context in which that term is used. “Connected to,” “forming on,” “forming over,” or other similar terms should generally be construed broadly to include situations where formations, depositions, and connections are direct between referenced elements or through one or more intermediaries between the referenced elements. These and other terms are to be construed in light of the context in which they are used in the present disclosure and as one of ordinary skill in the art would understand those terms in the disclosed context. The above definitions are not exclusive of other meanings that might be imparted to those terms based on the disclosed context.

Words of comparison, measurement, and timing such as “at the time,” “equivalent,” “during,” “complete,” and the like should be understood to mean “substantially at the time,” “substantially equivalent,” “substantially during,” “substantially complete,” etc., where “substantially” means that such comparisons, measurements, and timings are practicable to accomplish the implicitly or expressly stated desired result.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method of fabricating a semiconductor device comprising a three-dimensional vertical gate structure, the method comprising:
providing a substrate;
forming a plurality of layers over the substrate, the plurality of layers having alternating first composition material layers and second composition material layers;
forming an elongated post, the post extending from at least the top surface of the substrate and operable to provide support for the three-dimensional vertical gate structure.

2. The method of claim 1, further comprising:
identifying bit line and word line locations for the formation of a plurality of bit lines and word lines;
forming bit lines at the identified bit line locations; and
forming word lines at the identified word line locations;
wherein the forming the elongated post is performed in a selected area adjacent to one of the identified bit line locations.

3. The method of claim 2, wherein the forming the post comprises:
forming an elongated hole through the plurality of layers in the selected area, the hole being formed extending from at least the top surface of the substrate.

4. The method of claim 3, wherein the forming the post further comprises depositing a third composition material into the hole.

5. The method of claim 4, wherein the third composition material comprises nitride, the first composition material is a conductive material, and the second composition material is an insulative material.

6. The method of claim 5, wherein the forming the bit lines comprises:
removing the plurality of layers in areas not identified as the bit line locations; and
removing the second composition material from the second composition material layers in areas identified as the bit line locations.

7. The method of claim 6, further comprising forming a charge storage structure adjacent to the bit lines.

8. The method of claim 7, wherein the charge storage structure is formed by forming an oxide nitride oxide (ONO) layer.

9. The method of claim 7, further comprising depositing a conductive material adjacent to the charge storage structure.

10. The method of claim 4, further comprising removing the third composition material from the hole.

11. The method of claim 10, further comprising filling an insulative material into the hole after the removing of the third composition material from the hole.

12. The method of claim 9, wherein the forming the word lines comprises depositing a conductive material in areas identified as the word line locations.

13. The method of claim 3, wherein the third composition material is an insulative material, the first composition material is a conductive material, and the second composition material is an insulative material.

14. The method of claim 13, wherein the forming the bit lines comprises:
removing the plurality of layers in areas not identified as the bit line locations; and
removing the first composition material from the first composition material layers in areas identified as the bit line locations.

15. The method of claim 14, further comprising forming a macaroni conductive deposition layer over the sidewalls of the second composition material layers remaining after the removing of the first composition material from the first composition material layer, the macaroni conductive deposition layer comprising a thin layer of conductive material.

16. The method of claim 15, further comprising forming a charge storage structure adjacent to the bit lines.

17. The method of claim 16, wherein the charge storage structure is formed by forming an oxide nitride oxide (ONO) layer.

18. The method of claim 17, wherein the forming the word lines comprises depositing conductive material in areas identified as the word line locations.

19. The method of claim 3, wherein the forming the post further comprises removing a portion of each of the second composition material layers, the removed portion of each of the second composition material layers being the portion facing the formed hole.

20. The method of claim 19, wherein the forming the post further comprises depositing a third composition material into the hole and the removed portion.

21. The method of claim 2, further comprising forming a plurality of other elongated posts in other select areas adjacent to identified bit line locations, the other posts extending from at least the top surface of the substrate.

22. The method of claim 3, wherein the formed hole extends below the top surface of the substrate.

23. The method of claim 21, further comprising forming a top buttress connecting one of the elongated posts formed adjacent to a first side of the semiconductor device to another one of the elongated posts formed adjacent to a second side of the semiconductor device.

24. A semiconductor structure comprising:
a three-dimensional vertical gate structure having bit lines and word lines formed over a substrate; and
a plurality of elongated posts extending from at least a top surface of the substrate, the plurality of elongated posts formed adjacent to the three-dimensional vertical gate structure and operable to provide support for the three-dimensional vertical gate structure.

25. The semiconductor structure of claim 24, wherein the plurality of elongated posts are formed of an insulative material.

26. The semiconductor structure of claim 24, wherein the bit lines are formed of a conductive material.

27. The semiconductor structure of claim 24, wherein the bit lines are formed as a macaroni polysilicon deposition layer.

28. The semiconductor structure of claim 24, wherein each of the plurality of elongated posts comprise a plurality of protruded portions, each protruded portion protruding into a portion separating vertically consecutive bit lines.

29. The semiconductor structure of claim 24, further comprising a top buttress connecting one of the elongated posts formed adjacent to a first side of the three-dimensional vertical gate structure to another one of the elongated posts formed adjacent to a second side of the three-dimensional vertical gate structure.
